(19) United States
(12) Patent Application Publication
(10) Pub. No.: US 2024/0201237 A1
(43) Pub. Date: Jun. 20, 2024

(54) NON-GROUNDED MEASURMENT AVAILABILITY JUDGMENT DEVICE AND METHOD

(71) Applicant: Nippon Telegraph and Telephone Corporation, Tokyo (JP)

(72) Inventors: Naruto ARAI, Musashino-shi, Tokyo (JP); Masato MARUYAMA, Musashino-shi, Tokyo (JP); Jun KATO, Musashino-shi, Tokyo (JP)

(21) Appl. No.: 18/565,334

(22) PCT Filed: Jun. 4, 2021
(86) PCT No.: PCT/JP2021/021335

§ 371 Date: Nov. 29, 2023

(51) Int. Cl. G01R 23/02; G01R 35/00

(52) U.S. Cl. CPC G01R 23/02; G01R 35/005

(57) ABSTRACT

An ungrounded measurement possibility determination device that determines whether to ground a measuring instrument when measuring a voltage to ground of electromagnetic noise includes a determination table 35 in which a relationship between a measured frequency and an allowable value of the voltage to ground has been recorded, a first electrode 31 arranged on a floor of a room where the voltage to ground is to be measured, a second electrode 32 arranged on the floor, an oscillation unit 33 that inputs a frequency signal having the same frequency as the measured frequency to the first electrode 31, a voltage measurement unit 34 that measures a voltage value of a frequency signal induced by the second electrode 32, and a determination unit 36 that compares the voltage value induced by the second electrode 32 with the allowable value and determines that it is unnecessary to ground the measuring instrument for measuring the voltage to ground at a corresponding frequency in a case where the voltage value is larger than the allowable value.

### TECHNICAL FIELD

The present invention relates to an ungrounded measurement possibility determination device and a calibration method therefor.

### BACKGROUND ART

A metal cable such as a telephone line may induce electromagnetic noise that causes communication interruption or deterioration in communication speed (communication trouble). In a case where a communication trouble occurs, it is necessary to measure a voltage to ground of the electromagnetic noise generated in the cable in order to determine whether or not such a failure has been caused by the electromagnetic noise.

In order to accurately measure the voltage to ground of the electromagnetic noise, it is necessary to ground a measuring instrument. The measurement is generally performed by bringing a probe of the grounded measuring instrument into contact with a cable to be measured or by clamping a capacitive voltage probe capable of performing non-contact measurement to the cable (for example, Non Patent Literature 1).

### CITATION LIST

### Non Patent Literature

Non Patent Literature 1: Ryuichi KOBAYASHI et al. “A Novel Non-contact Capacitive Probe for Common-Mode Voltage Measurement”, IEICE TRANS. COMMUN., VOL. E90-B, NO. 6 June 2007

### SUMMARY OF INVENTION

### Technical Problem

However, an indoor power outlet may have no grounding electrode. In that case, it is not easy to ground a measuring instrument that measures a voltage to ground. In a case where there is no grounding electrode, it is necessary to drive a grounding rod into the ground and connect a cable extending from the grounding rod to the measuring instrument. This work is an excessive burden on a worker.

Meanwhile, in a case where a capacitance of the earth that is a capacitance between the measuring instrument and the ground is sufficiently large (impedance is small), it is possible to accurately measure the voltage to ground, without grounding the measuring instrument. In a case where the capacitance of the earth is small (impedance is large), an error of the voltage to ground increases, and thus the voltage to ground cannot be measured.

However, a magnitude of the capacitance of the earth of an environment to be measured cannot be known only by looking at a floor surface of the measurement environment. Therefore, there is a problem that the worker cannot determine whether to ground the measuring instrument in order to accurately measure the voltage to ground of electromagnetic noise.

The present invention has been made in view of the above problem, and an object thereof is to provide an ungrounded measurement possibility determination device capable of determining whether to ground a measuring instrument when measuring a voltage to ground of electromagnetic noise and also to provide a calibration method thereof.

### Solution to Problem

An ungrounded measurement possibility determination device according to an aspect of the present invention includes: a determination table in which a relationship between a measured frequency and an allowable value of a voltage to ground has been recorded; a first electrode and a second electrode arranged on a floor of a room where the voltage to ground is to be measured; an oscillation unit that inputs a frequency signal having the same frequency as the measured frequency to the first electrode; a voltage measurement unit that measures a voltage value of a frequency signal induced by the second electrode; and a determination unit that determines that it is unnecessary to ground a measuring instrument for measuring the voltage to ground at a corresponding frequency in a case where the voltage value is larger than the allowable value.

Further, a calibration method of an ungrounded measurement possibility determination device according to an aspect of the present invention is a calibration method of the above ungrounded measurement possibility determination device and includes: a preliminary step of inputting a frequency signal having a known frequency and amplitude from a grounded signal generator to a measuring instrument arranged on a dielectric plate placed on a floor of a grounded conductor, measuring the amplitude of the frequency signal by using the measuring instrument while increasing the number of dielectric plates until the amplitude exceeds the allowable value, and obtaining the number of dielectric plates before the amplitude exceeds the allowable value for each of a plurality of frequencies that are same as measured frequencies for measuring the voltage to ground; and a calibration step of placing the ungrounded measurement possibility determination device on the number of dielectric plates before the amplitude exceeds the allowable value corresponding to the measured frequency, the number of dielectric plates being stacked on the floor, causing the oscillation unit to input a frequency signal having the same frequency as the measured frequency to the first electrode facing the floor, causing the voltage measurement unit to measure a voltage value of a frequency signal induced by the second electrode arranged on the floor and set the voltage value as the allowable value corresponding to the measured frequency.

### Advantageous Effects of Invention

The present invention can provide an ungrounded measurement possibility determination device capable of determining whether to ground a measuring instrument when measuring a voltage to ground of electromagnetic noise and also provide a calibration method thereof.

### BRIEF DESCRIPTION OF DRAWINGS

FIG. 1 illustrates an equivalent circuit of a measurement system including a cable (noise source) to be measured and illustrates a case of grounding a measuring instrument.

FIG. 2 illustrates an equivalent circuit in a case where the measuring instrument of FIG. 1 is not grounded.

FIG. 3 is a configuration diagram illustrating a functional configuration example of an ungrounded measurement possibility determination device according to an embodiment of the present invention.

FIG. 4 is a schematic diagram illustrating a measurement environment used in a preliminary step.

FIG. 5 is a flowchart showing a procedure of a preliminary step.

FIG. 6 is a flowchart showing a procedure of a calibration step.

### DESCRIPTION OF EMBODIMENTS

Hereinafter, an embodiment of the present invention will be described with reference to the drawings. The same components in the plurality of drawings will be denoted by the same reference signs, and description thereof will be omitted.

### Concept of Present Invention

Before describing an embodiment of the present invention, a concept of the present invention will be described. An ungrounded measurement possibility determination device according to an embodiment of the present invention determines in advance an allowable error of a voltage to ground of a frequency to be measured and determines that it is necessary to ground a measuring instrument in a case where the voltage to ground exceeds the allowable error.

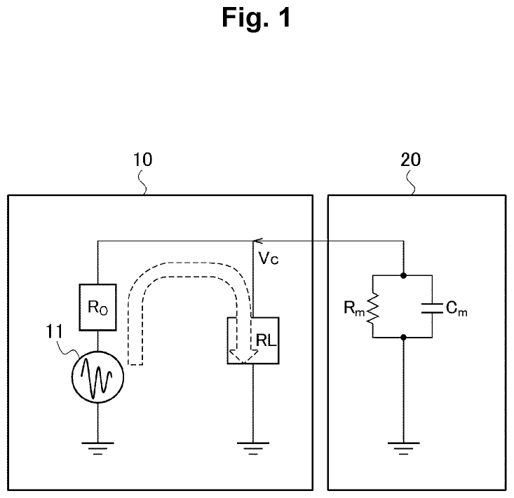

FIG. 1 illustrates an equivalent circuit of a measurement system including a cable (noise source) to be measured and illustrates a case of grounding a measuring instrument. Electromagnetic noise is represented by a noise source 11 and an output impedance Rₒ thereof. R_{L} denotes a load impedance of a cable 10.

The noise source 11 acts on the load impedance R_{L} of the cable 10 and generates a voltage to ground Vc. The voltage to ground Vc has a frequency characteristic.

The measuring instrument 20 measures the voltage to ground Vc with an input impedance in which an input resistance Rₘ and an input capacitance Cₘ are connected in parallel.

Before using the ungrounded measurement possibility determination device, a user determines frequency bands fa to fb in which the voltage to ground Vc is desired to be measured and an error E having an allowable magnitude.

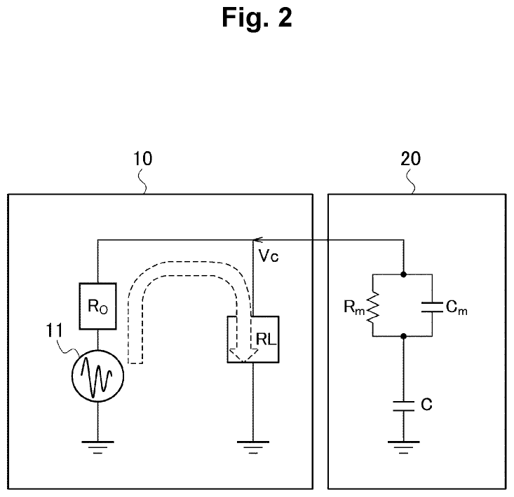

FIG. 2 illustrates an equivalent circuit in a case where the measuring instrument in the measurement system of FIG. 1 is not grounded. As illustrated in FIG. 2, a capacitance of the earth C is interposed between the input impedance of the measuring instrument 20 and the ground when the measuring instrument 20 is not grounded.

A difference (presence or absence of the capacitance of the earth C) illustrated in FIGS. 1 and 2 is generated in the equivalent circuit of the measurement system depending on whether or not the measuring instrument 20 is grounded. Therefore, a difference Xd between a measured voltage (voltage to ground Vc) obtained in a case where the measuring instrument 20 is grounded and a measured voltage obtained in a case where the measuring instrument is not grounded can be expressed by the following expression.

$$[ Math . 1 ]$$

$$X d = 20 log \vert \frac{1}{1 + \frac{\frac{1}{{R}_{m}} + j {ω C}_{m}}{j ω C}} \vert \qquad ( 1 )$$

Here, j denotes an imaginary unit, and @ denotes an angular frequency of the electromagnetic noise.

The difference Xd is obtained by determining, for each frequency, an allowable capacitance of the earth C that is the difference Xd obtained by the user. By doing this, the difference Xd is synonymous with being always smaller than the allowable error E within a range of 2πfa≤ω≤2πfb that is a condition determined by the user. That is, when the condition of Expression (1) is satisfied, a measurement result falls within the range of the allowable error E even in a case where the measuring instrument 20 is used without being grounded.

The ungrounded measurement possibility determination device according to the present embodiment determines whether or not a measurement environment for measuring the voltage to ground Vc of the electromagnetic noise satisfies the condition shown by Expression (1).

### (Ungrounded Measurement Possibility Determination Device)

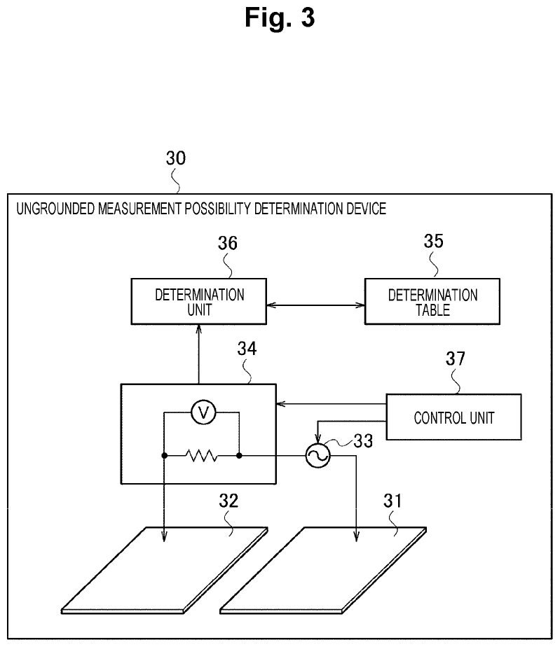

FIG. 3 is a configuration diagram illustrating a functional configuration example of the ungrounded measurement possibility determination device according to the embodiment of the present invention. An ungrounded measurement possibility determination device 30 in FIG. 3 determines whether or not it is necessary to ground the measuring instrument 20 (FIG. 1) when measuring the voltage to ground Vc of the electromagnetic noise.

The ungrounded measurement possibility determination device 30 includes a determination table 35, a first electrode 31, a second electrode 32, an oscillation unit 33, a voltage measurement unit 34, a determination unit 36, and a control unit 37. The determination table 35, the determination unit 36, and the control unit 37 can be implemented by a computer including, for example, a read-only memory (ROM), a random-access memory (RAM), and a central processing unit (CPU). In that case, processing content thereof is written as a program.

The determination table 35 is a table in which a relationship between a measured frequency and an allowable value of the voltage to ground Vc has been recorded. The allowable value of the voltage to ground Vc is a voltage value for determining that it is unnecessary to ground the measuring instrument 20 in a case where the voltage to ground Vc larger than the allowable value is measured and for determining that it is necessary to ground the measuring instrument 20 in a case where the voltage to ground Vc smaller than the allowable value is measured.

The determination table 35 is a table of sets of measured frequencies and voltage values, such as f1: 1.5 Vp-p, f2: 2.4 Vp-p, . . . Vp-p is a voltage value of a peak-to-peak amplitude of a frequency signal. The determination table 35 will be described later in detail.

The first electrode 31 is arranged on a floor (not illustrated) of a room where the voltage to ground Vc is to be measured. The first electrode 31 faces the ground and forms an electrostatic capacitance.

The second electrode 32 is arranged on the floor (not illustrated) of the same room. The second electrode 32 is arranged on the same plane as the first electrode 31.

The second electrode 32 also forms an electrostatic capacitance with the ground. The electrostatic capacitances formed by the first electrode 31 and the second electrode 32 are smaller as the first and second electrodes 31 and 32 are farther from the ground and are larger as the first and second electrodes 31 and 32 are closer to the ground.

The oscillation unit 33 inputs a frequency signal having the same frequency as the measured frequency to the first electrode 31. The frequency and amplitude of the frequency signal input by the oscillation unit 33 to the first electrode 31 are controlled by the control unit 37.

The voltage measurement unit 34 measures a voltage value of a frequency signal induced by the second electrode 32. A voltage induced by the second electrode 32 is small in a case where values of the electrostatic capacitances formed by the first electrode 31 and the second electrode 32 are large and is large in a case where the values of the electrostatic capacitances are small.

The determination unit 36 compares the voltage value of the frequency signal induced by the second electrode 32 with the allowable value and determines that it is unnecessary to ground the measuring instrument 20 for measuring the voltage to ground Vc at the corresponding frequency in a case where the voltage value is larger than the allowable value. The fact that the voltage value induced by the second electrode 32 is large means that an influence on the voltage to ground Vc is small because the values of the capacitances of the earth C formed between the first and second electrodes 31 and 32 and the ground are large.

The determination result by the determination unit 36 is displayed on a display unit (not illustrated) or the like to notify the user whether to ground the measuring instrument 20. The notification to the user may be performed by voice.

As described above, the ungrounded measurement possibility determination device 30 according to the present embodiment is an ungrounded measurement possibility determination device that determines whether to ground the measuring instrument 20 when measuring the voltage to ground Vc of the electromagnetic noise and includes the determination table 35 in which the relationship between the measured frequency and the allowable value of the voltage to ground Vc has been recorded, the first electrode 31 arranged on a floor of a room where the voltage to ground Vc is to be measured, the second electrode 32 arranged on the floor, the oscillation unit 33 that inputs a frequency signal having the same frequency as the measured frequency to the first electrode 31, the voltage measurement unit 34 that measures a voltage value of a frequency signal induced by the second electrode 32, and the determination unit 36 that compares the voltage value with the allowable value and determines that it is unnecessary to ground the measuring instrument 20 for measuring the voltage to ground Vc at the corresponding frequency in a case where the voltage value is larger than the allowable value. Therefore, it is possible to provide the ungrounded measurement possibility determination device 30 capable of determining whether to ground the measuring instrument 20 when measuring the voltage to ground Vc of the cable.

### (Calibration Method)

A calibration method of the ungrounded measurement possibility determination device 30 will be described. The calibration method is divided into two steps of a preliminary step and a calibration step.

The preliminary step is a step of obtaining the number of dielectric plates corresponding to the measured frequency of the electromagnetic noise. The dielectric plate simulates the electrostatic capacitance between the measuring instrument 20 and the ground.

### (Preliminary Step)

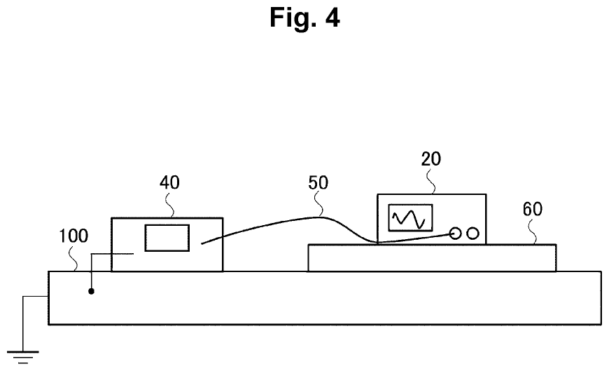

FIG. 4 is a schematic diagram illustrating a measurement environment used in the preliminary step. The measurement environment includes a grounded floor 100, a signal generator 40, a cable 50, a dielectric plate 60, and the measuring instrument 20.

The floor 100 is, for example, a floor of a sealed room whose floor surface is made from a conductor. The signal generator 40 is an oscillator capable of generating a sinusoidal frequency signal. The signal generator 40 is grounded.

The measuring instrument 20 is desired to be used in a measurement site of the electromagnetic noise and is placed on the dielectric plate 60 arranged on the floor 100. The measuring instrument 20 is, for example, an oscilloscope capable of measuring an amplitude of a frequency signal. In a broad sense, the measuring instrument is a voltmeter.

The signal generator 40 and the measuring instrument 20 are connected by the cable 50. The cable 50 corresponds to the cable 10 described above.

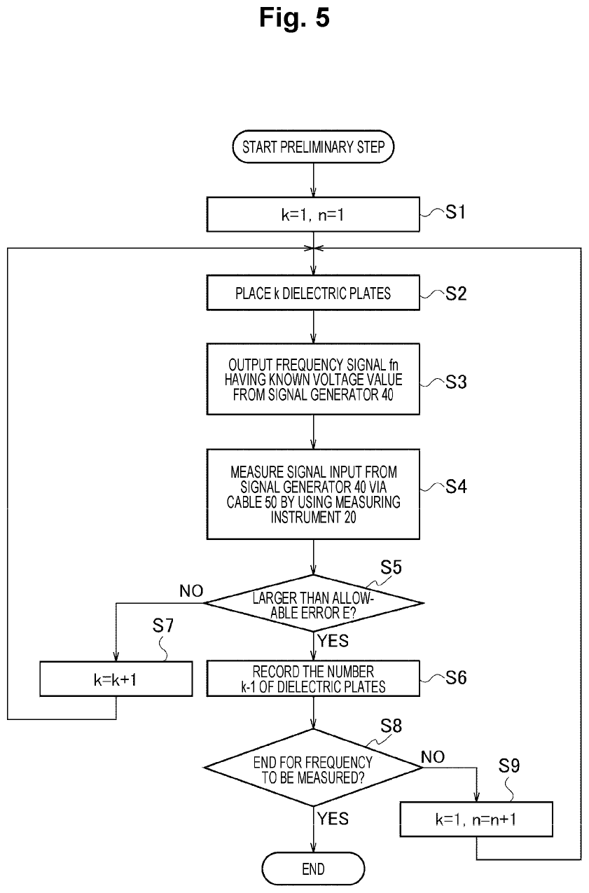

FIG. 5 is a flowchart showing a procedure of the preliminary step. The preliminary step will be described in detail with reference to FIG. 5.

When the preliminary step starts, first, variables k and n are initialized to 1 (step S1). The variable k denotes the number of dielectric plates 60, and k=1 indicates that the number of dielectric plates 60 is one.

The variable n denotes a frequency of a measured frequency. In a case where frequency bands to be measured are fa to fb, the variable denotes a measured frequency of each of n frequency bands from which the above frequency bands are divided. For example, fa=f1 and fb=fn.

First, one dielectric plate 60 is inserted between the measuring instrument 20 and the floor 100 (step S2).

Next, a frequency signal f1 having a known voltage value is generated from the signal generator 40, and the frequency signal f1 is input to the measuring instrument 20 via the cable 50 (step S3).

Next, the measuring instrument 20 measures the frequency signal f1 (step S4). At this time, the user determines whether or not a measured value by the measuring instrument 20 exceeds the allowable error E (the difference Xd described above) (step S5).

When the measured value is less than or equal to the error E (NO in step S5), the variable k is incremented (step S6), and the procedure in steps S2 to S5 is repeated.

By repeating steps S2 to S5, the number of dielectric plates 60 increases, and the value of the electrostatic capacitance between the measuring instrument 20 and the floor 100 gradually decreases. When the number of dielectric plates 60 reaches a certain number, the measured value exceeds the allowable error E (YES in step S5).

When the error of the measured value exceeds the error E, the number k of dielectric plates 60 is k=k−1, and the frequency signal f1 and the number k are recorded in association with each other (step S6). Here, the number k of dielectric plates 60 before the error of the measured value exceeds the error E is recorded in association with the frequency signal f1.

Next, for the next frequency signal f2, a variable k denoting the number of dielectric plates is initialized (k=1), and the procedure in steps S2 to S5 is repeated (loop of NO in step S7).

By repeating the procedure described above, it is possible to obtain information indicating a relationship between the frequency signals f1 to fn and the number k of dielectric plates 60 before the error of the voltage to ground Vc exceeds the error E as shown in the following table. The number k of dielectric plates 60 corresponds to the allowable capacitance of the earth C described above.

TABLE 1

| Frequency signal | f1 | f2 | . . . | fn − 1 | fn |
|---|---|---|---|---|---|
| Dielectric plates k | 4 | 5 | . . . | 4 | 2 |

Table 1 shows the upper limit number of dielectric plates 60 in which the error of the measured value by the measuring instrument 20 at a frequency of each of the frequency signals f1 to fn is less than or equal to the error E. The upper limit number is information correlated with a minimum capacitance of the earth C in which a measurement error of the voltage to ground Vc does not exceed the allowable error E.

That is, in a case where the number of dielectric plates 60 is increased to the upper limit number or more, the capacitance of the earth C decreases (impedance increases), and the error of the measured value exceeds the allowable error E. The number k of dielectric plates 60 shown in Table 1 is the number of dielectric plates 60 forming the minimum capacitance of the earth C in which the error of the measured value does not exceed the error E.

### (Calibration Step)

The calibration step is a step of generating the determination table 35 of the ungrounded measurement possibility determination device 30. The calibration step is performed by placing the ungrounded measurement possibility determination device 30 on the number of dielectric plates 60 shown in Table 1 placed on the floor 100, inputting a frequency signal from the oscillation unit 33 of the ungrounded measurement possibility determination device 30 to the first electrode 31, and measuring a voltage value of the frequency signal induced by the second electrode 32 by using the voltage measurement unit 34.

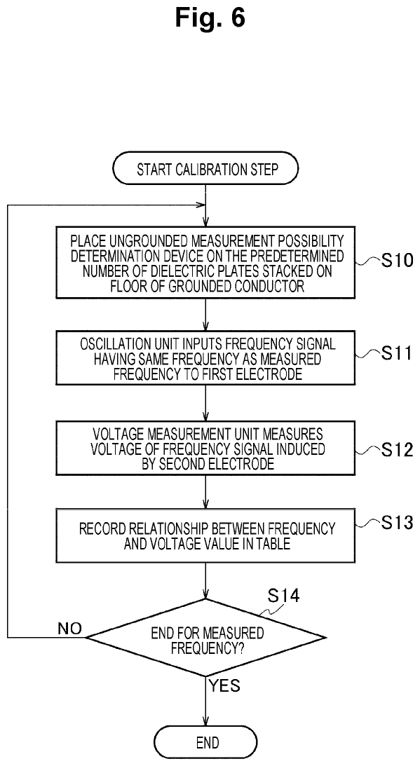

FIG. 6 is a flowchart showing a procedure of the calibration step. The calibration step will be described in detail with reference to FIG. 6.

When the calibration step starts, the user acquires information regarding the number of dielectric plates 60 associated with the measured frequency (frequency signal) from Table 1 and stacks the number of dielectric plates 60 on the floor 100. Then, the ungrounded measurement possibility determination device 30 is placed on the stacked dielectric plates 60 (step S10). In the calibration step, the signal generator 40, the cable 50, and the measuring instrument 20 are unnecessary. A frequency signal generated by the oscillation unit 33 is used instead of the signal generator 40. Further, a voltage measurement unit 34 is used instead of the measuring instrument 20.

For example, in a case where four dielectric plates 60 are stacked, the oscillation unit 33 inputs the frequency signal f1 having the same frequency as the measured frequency to the first electrode 31 (step S11).

Next, the voltage measurement unit 34 measures a voltage value of the frequency signal f1 induced by the second electrode 32 (step S12). Then, the control unit 37 records the frequency signal f1 and the voltage value thereof in association with each other in the RAM, for example (step S13).

The procedure in steps S10 to S13 is repeated for all the frequency signals f1 to fn (NO in step S14). In this manner, the determination table 35 shown in Table 2 is generated.

TABLE 2

| Frequency signal | f1 | f2 | . . . | fn − 1 | fn |
|---|---|---|---|---|---|
| Voltage value | 1.5 | 2.4 | . . . | 2.1 | 2.0 |
| | Vp − p | Vp − p | | Vp − p | Vp − p |

s

The voltage values in Table 2 are allowable values of the voltage to ground Vc.

The voltage values measured by the voltage measurement unit 34, which are the allowable values, are obtained by dividing the voltage value (amplitude) of the frequency signal output from the oscillation unit 33 by a capacitance of the earth C1 (not illustrated) between the first electrode 31 and the ground and a capacitance of the earth C2 (not illustrated) between the ground and the second electrode 32. Therefore, in a case where the capacitances of the earth C1 and C2 are small, the voltage value measured by the voltage measurement unit 34 is small. Meanwhile, in a case where the capacitances of the earth C1 and C2 are large, the voltage value measured by the voltage measurement unit 34 is large.

The number of dielectric plates 60 stacked on the floor 100 correlates with a minimum value of the capacitance of the earth C at which it is unnecessary to ground the measuring instrument 20. In a case where the voltage value measured by the voltage measurement unit 34 while the number of dielectric plates 60 is being stacked is larger than the allowable value (voltage value) shown in Table 2, it is unnecessary to ground the measuring instrument 20. That is, in this case, the capacitances of the earth C1 and C2 are large to some extent, and thus it is possible to determine that the voltage to ground Vc can be measured with an error less than or equal to the allowable error E.

Conversely, in a case where the voltage value measured by the voltage measurement unit 34 while the number of dielectric plates 60 is being stacked is smaller than the allowable value (voltage value) shown in Table 2, it is necessary to ground the measuring instrument 20. The fact that the voltage value measured by the voltage measurement unit 34 is smaller than the allowable value means that the voltage to ground Vc includes an error larger than or equal to the allowable error E because the capacitances of the earth C1 and C2 are small (impedances are large). Therefore, in this case, it is necessary to ground the measuring instrument 20 in order to cancel the capacitances of the earth C1 and C2 (FIG. 2-FIG. 1).

As described above, the determination table 35 according to the present embodiment is obtained by inputting a frequency signal having a known voltage value from the grounded signal generator 40 to the measuring instrument 20 arranged on the floor 100 of a grounded conductor via the dielectric plate 60 having a predetermined thickness, measuring the voltage value of the frequency signal while increasing the number of dielectric plates 60 until the voltage value exceeds the allowable value in the measuring instrument 20, obtaining the number of dielectric plates 60 before the voltage value exceeds the allowable value, placing the ungrounded measurement possibility determination device 30 itself on the number of dielectric plates stacked on the floor 100, and recording the voltage value measured by the voltage measurement unit 34 in association with the measured frequency. This makes it possible to determine whether to ground the measuring instrument 20.

Further, the calibration method of the ungrounded measurement possibility determination device 30 according to the present embodiment includes: the preliminary step of inputting a frequency signal having a known frequency and amplitude from the grounded signal generator 40 to the measuring instrument 20 arranged on the dielectric plate 60 placed on the floor 100 of the grounded conductor, measuring the amplitude of the frequency signal by using the measuring instrument 20 while increasing the number of dielectric plates 60 until the amplitude exceeds the allowable value, and obtaining the number of dielectric plates 60 before the amplitude exceeds the allowable value for each of a plurality of frequencies that are same as measured frequencies for measuring the voltage to ground Vc; and a calibration step of placing the ungrounded measurement possibility determination device 30 on the number of dielectric plates 60 before the amplitude exceeds the allowable value corresponding to the measured frequency, the number of dielectric plates being stacked on the floor 100, causing the oscillation unit 33 to input a frequency signal having the same frequency as the measured frequency to the first electrode 31 facing the floor 100, causing the voltage measurement unit 34 to measure a voltage value of a frequency signal induced by the second electrode 32 arranged on the floor 100 and set the voltage value as the allowable value corresponding to the measured frequency. This makes it possible to calibrate the ungrounded measurement possibility determination device 30.

As described above, the ungrounded measurement possibility determination device 30 according to the present embodiment can determine whether to ground the measuring instrument when measuring the voltage to ground Vc of the electromagnetic noise. That is, it is possible to determine whether or not the voltage to ground of the electromagnetic noise can be accurately measured even without grounding. This makes it possible to reduce the burden on the worker.

In the above embodiment, an example has been described in which the voltage to ground Vc of the electromagnetic noise generated in the cables 10 and 50 is measured to determine whether to perform grounding. However, the present invention is not limited to this example. A target whose voltage to ground Vc of the electromagnetic noise is measured is not limited to the cable. As long as the target is a metal member that induces electromagnetic noise, it is possible to determine whether to ground the measuring instrument in an environment in which the member (for example, a metal table) is added.

An example has been described in which the second electrode 32 is provided on the same plane as the first electrode 31, but the present invention is not limited to this example. The second electrode 32 may be arranged on the floor 100.

In the above embodiment, an example has been described in which the determination result by the determination unit 36 is displayed on the display unit (not illustrated) or the like. However, the present invention is not limited to this example. The determination result may be expressed by a voice or the like.

As described above, it is needless to say that the present invention includes various embodiments and the like not described herein. Therefore, the scope of the present invention is defined only by subject matters in the appended claims valid based on the above description.

### REFERENCE SIGNS LIST

10, 50 Cable
20 Measuring instrument
30 Ungrounded measurement possibility determination device
31 First electrode
32 Second electrode
33 Oscillation unit
34 Voltage measurement unit
35 Determination table
36 Determination unit
40 Signal generator
60 Dielectric plate

1. An ungrounded measurement possibility determination device, comprising:
a determination table in which a relationship between a measured frequency and an allowable value of a voltage to ground has been recorded;
a first electrode and a second electrode arranged on a floor of a room where the voltage to ground is to be measured;
an oscillation unit, including one or more processors, configured to input a frequency signal having the same frequency as the measured frequency to the first electrode;
a voltage measurement unit, including one or more processors, configured to measure a voltage value of a frequency signal induced by the second electrode; and
a determination unit, including one or more processors, configured to determine that it is unnecessary to ground a measuring instrument for measuring the voltage to ground at a corresponding frequency in a case where the voltage value is larger than the allowable value.

2. The ungrounded measurement possibility determination device according to claim 1, wherein
the determination table is obtained by inputting a frequency signal having a known voltage value from a grounded signal generator to the measuring instrument arranged on a floor of a grounded conductor via a dielectric plate having a predetermined thickness, measuring the voltage value of the frequency signal while increasing the number of dielectric plates until the voltage value exceeds the allowable value in the measuring instrument, obtaining the number of dielectric plates before the voltage value exceeds the allowable value, placing the ungrounded measurement possibility determination device itself on the number of dielectric plates stacked on the floor, and recording the voltage value measured by the voltage measurement unit in association with the measured frequency.

3. A calibration method of an ungrounded measurement possibility determination device that includes a first electrode, a second electrode, an oscillation unit, and a voltage measurement unit and determines, based on an allowable value, whether to perform grounding when measuring a voltage to ground of electromagnetic noise, the calibration method comprising:
inputting a frequency signal having a known frequency and amplitude from a grounded signal generator to a measuring instrument arranged on a dielectric plate placed on a floor of a grounded conductor, measuring the amplitude of the frequency signal by using the measuring instrument while increasing the number of dielectric plates until the amplitude exceeds the allowable value, and obtaining the number of dielectric plates before the amplitude exceeds the allowable value for each of a plurality of frequencies that are same as measured frequencies for measuring the voltage to ground; and
placing the ungrounded measurement possibility determination device on the number of dielectric plates before the amplitude exceeds the allowable value corresponding to the measured frequency, the number of dielectric plates being stacked on the floor, causing the oscillation unit to input a frequency signal having the same frequency as the measured frequency to the first electrode facing the floor, causing the voltage measurement unit to measure a voltage value of a frequency signal induced by the second electrode arranged on the floor and set the voltage value as the allowable value corresponding to the measured frequency.
